(19) United States
(12) Patent Application Publication
(10) Pub. No.: US 2009/0017638 A1
(43) Pub. Date: Jan. 15, 2009

(54) Substrate processing apparatus and method for manufacturing semiconductor device

(75) Inventors: Akihito Yoshino, Toyama-shi (JP); Takashi Ozaki, Toyama-shi (JP); Toshihiko Yonejima, Toyama-shi (JP)

Correspondence Address: OLIFF & BERRIDGE, PLC, P.O. BOX 320850, ALEXANDRIA, VA, 22320-4850, US

(73) Assignee: HITACHI KOKUSAI ELECTRIC INC., TOKYO (JP)

(21) Appl. No.: 12/073,009

(22) Filed: Feb. 28, 2008

(30) Foreign Application Priority Data
Feb. 28, 2007 (JP) 2007-048689
Feb. 6, 2008 (JP) 2008-026574

(51) Int. Cl. H01L 21/30; C23C 16/00

(52) U.S. Cl. 438/758; 118/724; 257/E21.211

(57) ABSTRACT

It is intended to provide a substrate processing apparatus and a semiconductor device manufacturing method capable of suppressing formation of a film inside a nozzle and extending a replacement or maintenance cycle of the nozzle, thereby realizing improvement in operation rate of the apparatus. A substrate processing apparatus comprising: a reaction container for performing a processing for generating a film containing a plurality of elements on a substrate; a heater for heating an inside of the reaction container; at least one nozzle that is provided inside the reaction container in such a fashion that at least a part thereof is opposed to the heater for supplying a first gas containing at least one of the plurality of elements forming the film and capable of depositing a film by itself into the reaction container; and a circulation pipe that is provided in such a fashion as to cover at least the part of the nozzle opposed to the heater for supplying a second gas containing at least one of the plurality of elements forming the film and not capable of depositing a film by itself into the reaction container after circulating the second gas thereinside.

### BACKGROUND OF THE INVENTION

1. Field of the Invention

This invention relates to a substrate processing apparatus for processing a substrate such as a semiconductor wafer and a glass substrate as well as to a method for manufacturing a semiconductor device.

2. Description of the Related Art

In the substrate processing apparatuses of this type, it is necessary to supply a reaction gas at an intermediate point in a substrate alignment region in the case of performing formation of a film on a surface of a substrate by CVD (Chemical Vapor Deposition), and a substrate processing apparatus provided with a nozzle for supplying the reaction gas at the intermediate point of the substrate alignment region has been known (see Patent Publication 1).

Patent Publication 1; JP-A-2005-286005

### SUMMARY OF THE INVENTION

However, a film is formed on a surface and an inside of the nozzle by the film formation processing in the above-described substrate processing apparatus. The film is formed inside the nozzle since the nozzle for supplying the gas to the substrate alignment region is disposed at a region opposed to a heater, and hence the nozzle is heated to a film formation temperature. Also, since the inside of the nozzle is generally smaller in capacity than a process chamber, a pressure inside the nozzle is larger than that inside the process chamber. Accordingly, a film formation speed of the film formed inside the nozzle becomes higher than that of the film formed inside the process chamber to cause necessity of replacement or maintenance of the nozzle at a shorter interval than that of other members (e.g. outer tube, inner tube, boat, etc.) constituting the process chamber, resulting in a reduction in operation rate of the apparatus.

An object of this invention is to provide a substrate processing apparatus and a method for producing a semiconductor device, which solve the above-described problem and realize improvement in operation rate of the apparatus.

According to a first aspect of this invention, there is provided a substrate processing apparatus comprising: a reaction container for performing a processing for generating a film containing a plurality of elements on a substrate; a heater for heating an inside of the reaction container; at least one nozzle that is provided inside the reaction container in such a fashion that at least a part thereof is opposed to the heater for supplying a first gas containing at least one of the plurality of elements forming the film and capable of depositing a film by itself into the reaction container; and a circulation pipe that is provided in such a fashion as to cover at least the part of the nozzle opposed to the heater for supplying a second gas containing at least one of the plurality of elements forming the film and not capable of depositing a film by itself into the reaction container after circulating the second gas thereinside.

According to a second aspect of this invention, there is provided a substrate processing apparatus comprising: a reaction container for performing a processing for generating a silicon nitride film on a substrate; a heater for heating an inside of the reaction container; a plurality of nozzles that are provided inside the reaction container in such a fashion that at least a part of each of the nozzles is opposed to the heater, the nozzles being different in length one another and supplying a silane-based gas into the reaction container; and a plurality of circulation pipes that are provided in such a fashion as to cover at least the parts of the nozzles opposed to the heater respectively for supplying an ammonium gas into the reaction container after circulating the ammonium gas thereinside.

According to a third aspect of this invention, there is provided a method for manufacturing a semiconductor device, comprising the steps of: transferring a substrate into a reaction container; performing, in a state where an inside of the reaction container is heated by a heater, a processing for generating a film containing a plurality of elements on the substrate by supplying a first gas containing at least one of the plurality of elements forming the film and capable of depositing a film by itself from at least one nozzle provided inside the reaction container in such a fashion that at least a part thereof is opposed to the heater into the reaction container and supplying a second gas containing at least one of the plurality of elements forming the film and not capable of depositing a film by itself from a circulation pipe provided in such a fashion as to cover at least the part of the nozzle opposed to the heater into the reaction container after circulating the second gas thereinside; and transferring the processed substrate from the reaction container.

According to this invention, since the substrate processing apparatus comprises the circulation pipe provided in such a fashion as to cover at least the part of the first gas supply nozzle opposed to the heater and supplies the second gas that is different from the first gas into the reaction container after circulating the second gas thereinside, it is possible to suppress formation of a film inside the nozzle by the cooling effect of the nozzle by the second gas and to extend a replacement or maintenance cycle of the nozzle, thereby realizing improvement in operation rate of the apparatus. Also, since the second gas containing at least one of the plurality of elements forming the film to be generated and not capable of depositing a film by itself is circulated inside the circulation pipe to be supplied into the reaction container, it is possible to prevent a change in ratio of each of the first gas and the second gas by controlling a flow rate of the second gas, thereby enabling formation of films having uniformity and homogeneity that are equal to or superior to those achieved by conventional technologies.

### BRIEF DESCRIPTION OF THE DRAWINGS

FIG. 1 is a sectional view showing a substrate processing apparatus according to a first embodiment of this invention.

FIG. 2A is a diagram showing a nozzle of Comparative Example.

FIG. 2B is a diagram showing a nozzle and a circulation pipe in the first embodiment.

FIG. 2C is a diagram showing a nozzle and a circulation pipe in a second embodiment.

FIG. 3 is a schematic diagram showing a detailed structure of a gas supply system of a substrate processing apparatus 100 of Example 1.

FIG. 4A is a schematic diagram showing a detailed structure of a gas supply system of a substrate processing apparatus 100 used in a first modification example.

FIG. 4B is a side view showing a circulation pipe when a diameter of a NH₃ injection aperture is changed.

FIG. 4C is a side view showing a circulation pipe when a pitch of NH₃ injection aperture alignment is changed.

FIG. 5 is a schematic diagram showing a detailed structure of a gas supply system of a substrate processing apparatus 100 used in a second modification example.

FIG. 6A is a schematic diagram showing a detailed structure of a gas supply system of a substrate processing apparatus 100 used in a third modification example.

FIG. 6B is a perspective view showing a nozzle and a circulation pipe.

### DESCRIPTION OF THE PREFERRED EMBODIMENTS

Hereinafter, the first embodiment of this invention will be described based on the drawings.

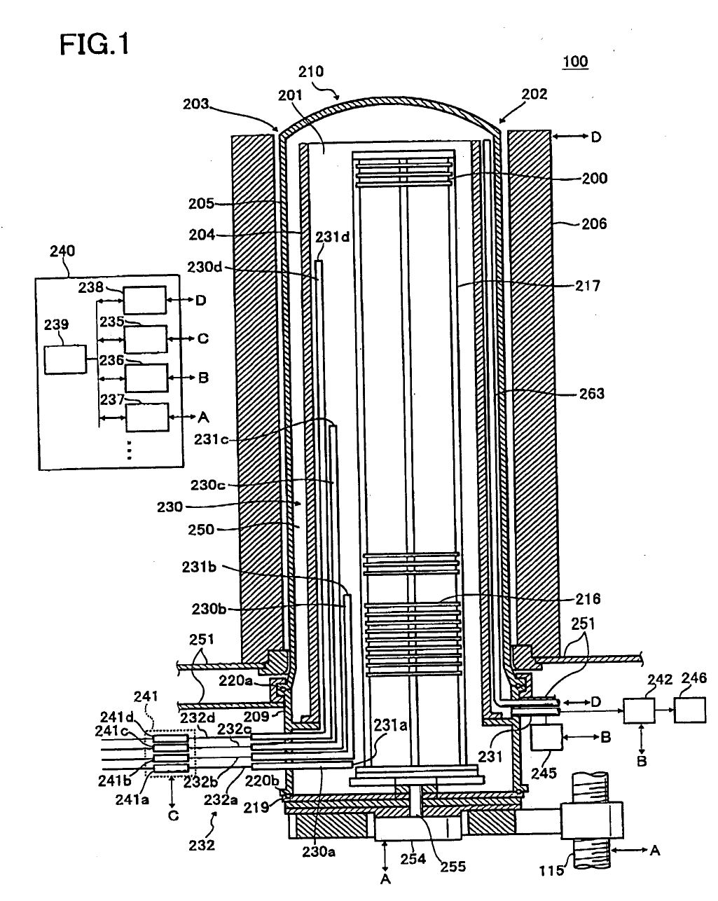

FIG. 1 is a schematic diagram showing processing furnace 202 of a substrate 100 suitably used in the first embodiment of this invention, which is shown as a linear sectional view.

As shown in FIG. 1, the processing furnace 202 has a heater 206 serving as a heating mechanism for heating an inside of a process tube 203 described later in this specification. The heater 206 has a cylindrical shape and is vertically mounted as being supported by a heater base 251 serving as a holding plate.

The process tube 203 is provided inside the heater 206 in a concentric fashion with the heater 206 and serves as a reaction tube for processing a wafer 200. The process tube 203 is formed of an inner tube 204 serving as an inner reaction tube and an outer tube 205 provided outside the inner tube 204 and serving as an outer reaction tube. The inner tube 204 is made from a heat resistant material such as quartz (SiO₂) and silicon carbide (SiC) and has a cylindrical shape with opened upper and lower ends. In a hollow part of the inner tube 204, a process chamber 201 is formed to house the wafers 200 as substrates in a state where the wafers 200 that keep horizontal posture as being supported by a boat 217 described later in this specification are aligned along a vertical direction in a multistage fashion. The outer tube 205 is made from a heat resistant material such as quartz and silicon carbide and has an inner diameter that is larger than an outer diameter of the inner tube 204 and a cylindrical shape with a closed upper end and an opened lower end. The outer tube is provided concentrically with the inner tube 204.

A manifold 209 is provided below and in a concentric fashion with the outer tube 205. The manifold 209 is made from a stainless steel, for example, and has a cylindrical shape with opened upper and lower ends. The manifold 209 is engaged with the inner tube 204 and the outer tube 205 to support the tubes 204 and 205. An O-ring 220a serving as a sealing member is provided between the manifold 209 and the outer tube 205. Since the manifold 209 is supported by the heater base 251, the process tube 203 is in the vertically mounted state. A reaction container 210 is formed of the process tube 203 and the manifold 209.

A nozzle 230 for supplying a reaction gas to the process tube 203 is connected to the manifold 209 in such a fashion as to provide communication with the inside of the process chamber 201, and a gas supply pipe 232 is connected to the nozzle 230. A reaction gas supply source (not shown) and an inert gas supply source (not shown) are connected at an upstream side of the gas supply pipe 232 via an MFC (mass flow controller) 241, the upstream side being opposite to a connection side with the nozzle 230. A gas flow rate control unit 235 is electrically connected to the MFC 241 so that a flow rate of a gas to be supplied is controlled to a desired value at a desired timing.

The manifold 209 is provided with a discharge pipe 231 for discharging atmosphere inside the process chamber 201. The discharge pipe 231 is disposed at a lower end of a cylindrical space 250 defined by a gap between the inner tube 204 and the outer tube 205 and communicated with the cylindrical space 250. An evacuation device 246 such as a vacuum pump is connected to a downstream side of the discharge pipe 231 via a pressure adjustment device 242 such as a pressure sensor 245 serving as a pressure detector and an APC (Auto-Pressure Controller) valve, the downstream side being opposite to the side at which the manifold 209 is connected. Thus, the pressure inside the process chamber 201 is evacuated to be a predetermined pressure (vacuum degree). A pressure control unit 236 is electrically connected to the pressure adjustment device 242 and the pressure sensor 245 and controls the pressure inside the process chamber 201 to a desired pressure at a desired timing by means of the pressure adjustment device 242 and based on a pressure detected by the pressure sensor 245.

A sealing cap 219 capable of tightly sealing the lower end opening of the manifold 209 is provided below the manifold 209 as a furnace cover. The sealing cap 219 is brought into contact with the lower end of the manifold 209 from a vertically lower direction. The sealing cap 219 is made from a metal such as a stainless steel, for example, and has a circular shape. An O-ring 220b serving as a sealing member to be brought into contact with the lower end of the manifold 209 is provided on an upper surface of the sealing cap 219. At a side of the sealing cap 219 that is opposite to the process chamber 201, a rotation mechanism 254 for rotating a boat is provided. A rotation shaft 255 of the rotation mechanism 254 penetrates through the sealing cap 219 to be connected to a boat 217 described later in this specification and rotates the wafer 200 by rotating the boat 217. The sealing cap 219 is elevated in the vertical direction by a boat elevator 115 disposed vertically outside the process tube 203 and serving as an elevation mechanism, so that the boat 217 is transferred into and from the process chamber 201. A driving control unit 237 is electrically connected to the rotation mechanism 254 and the boat elevator 115, so that the rotation mechanism 254 and the boat elevator 115 are controlled at a desired timing to perform a desired operation.

The boat 217 serving as a substrate support member is made from a heat resistant material such as quartz and has a structure of retaining a plurality of the wafers 200 in a state where the wafers 200 at the horizontal posture are aligned in a multistage fashion with centers thereof being kept in line with one another. A plurality of heat insulation panels 216 at a horizontal posture, each of which serves as a heat insulating member made from a heat resistant material such as quartz and silicon carbide and has a circular shape, are disposed in a multistage fashion, so that the heat from the heater 206 is hardly transferred to the manifold 209.

A temperature sensor 263 serving as a temperature detector is provided inside the process tube 203. A temperature control unit 238 is electrically connected to the heater 206 and the temperature sensor 263 so as to control a temperature inside the process chamber 201 to a desired temperature distribution at a desired timing by adjusting energization to the heater 206 based on temperature information detected by the temperature sensor 263.

The gas flow rate control unit 235, the pressure control unit 236, the driving control unit 237, and the temperature control unit 238 form an operation unit and input/output unit and are electrically connected to a main control unit 239 for controlling the whole substrate processing apparatus. The gas flow rate control unit 235, the pressure control unit 236, the driving control unit 237, the temperature control unit 238, and the main control unit 239 are formed as a controller 240.

Hereinafter, a method of forming a thin film on the wafer 200 by CVD will be described as one process step for a semiconductor device manufacturing process using the processing furnace 202 according to the above-described constitution. In the following description, operations of the component parts forming the substrate processing apparatus are controlled by the controller 240.

When a plurality of the wafers 200 are inserted into the boat 217 (wafer charging), the boat 217 retaining the wafers 200 is elevated upward by the boat elevator 115 to be transferred into the process chamber 201 (boat loading) as shown in FIG. 1. In this state, the sealing cap 219 seals the lower end of the manifold 209 via the O-ring 220b.

The process chamber 201 is evacuated by the evacuation device 246 so that the desired pressure (vacuum degree) is achieved. In this case, the pressure inside the pressure chamber 201 is measured by the pressure sensor 245, and the pressure adjustment device 242 is feedback-controlled based on the measured pressure. Also, the heater 206 heats the process chamber so that the desired temperature is achieved inside the process chamber 210. In this case, energization to the heater 206 is feedback-controlled based on the temperature information detected by the temperature sensor 263 so that the desired temperature distribution is achieved inside the process chamber 201. Subsequently, the wafers 200 are rotated when the boat 217 is rotated by the rotation mechanism 254.

Subsequently, the reaction gas supplied from the reaction gas supply source and controlled to the desired flow rate by the MFC 241 is flown through the gas supply pipe 232 to be introduced into the process chamber 201 (process tube 203) from the nozzle 230. The thus-introduced reaction gas rises inside the process chamber 201 to flow into the cylindrical space 250 from the upper end opening of the inner tube 204 and then exits from the discharge pipe 231. When the reaction gas contacts surfaces of the wafers 200 as passing through the process chamber 201, a thin film is deposited on the surfaces of the wafers 200 by the thermal CVD reaction.

After a predetermined processing time has elapsed, the inert gas is supplied from the inert gas supply source to substitute the inside of the process chamber 201 by the inert gas, and the pressure inside the process chamber 201 is returned to an ordinary pressure.

After that, the sealing cap 219 is lowered by the boat elevator 115, and the lower end of the manifold 209 is opened, so that the processed wafers 200 are transferred to the outside of the process tube 203 (boat unloading) from the lower end of the manifold 209 as being retained in the boat 217. After that, the processed wafers 200 are taken out from the boat 217 (wafer discharge).

Hereinafter, the nozzle 230 and a peripheral structure of the nozzle 230 will be described in detail.

As shown in FIG. 1, the nozzle 230 is formed of a first nozzle 230a having a substantially I-shape (straight nozzle) and a second nozzle 230b, a third nozzle 230c, and a fourth nozzle 230d having a substantially L-shape (L type nozzle). The first nozzle 230a is also referred to as a short nozzle, and each of the second, third, and fourth nozzles 230b, 230c, and 230d is also referred to as a long nozzle. At least a part of the second, third, and fourth nozzles 230b, 230c, and 230d is disposed inside the process tube 203 in such a fashion as to oppose to the heater 206, and gas injection apertures 231b, 231c, and 231d of the second, third, and fourth nozzles 230b, 230c, and 230d are disposed at different positions along a vertical direction inside the substrate alignment region. Therefore, the second, third, and fourth nozzles 230b, 230c, and 230d supply the reaction gas to the process tube 203 at the intermediate points in the substrate alignment region. The first nozzle 230a supplies the reaction gas to the process tube 203 from an upstream side of the substrate alignment region, which is further upstream from a heat insulating plate alignment region. Also, a circulation pipe 270 (not shown in FIG. 1) described later in this specification is provided around the nozzle 230 (at least one of the second, third, and fourth nozzles 230b, 230c, and 230d, for example).

The gas supply pipe 232 is formed of a first gas supply pipe 232a, a second gas supply pipe 232b, a third gas supply pipe 232c, and a fourth gas supply pipe 232d. The mass flow controller (MFC) 241 is formed of a first MFC 241a, a second MFC 241b, a third MFC 241c, and a fourth MFC 241d.

The first gas supply pipe 232a is connected to the first nozzle 230a via the first MFC 241a. The second gas supply pipe 232b is connected to the second nozzle 230b via the second MFC 241b. The third gas supply pipe 232c is connected to the third nozzle 230c via the third MFC 241c. The fourth gas supply pipe 232d is connected to the fourth nozzle 230d via the fourth MFC 241d.

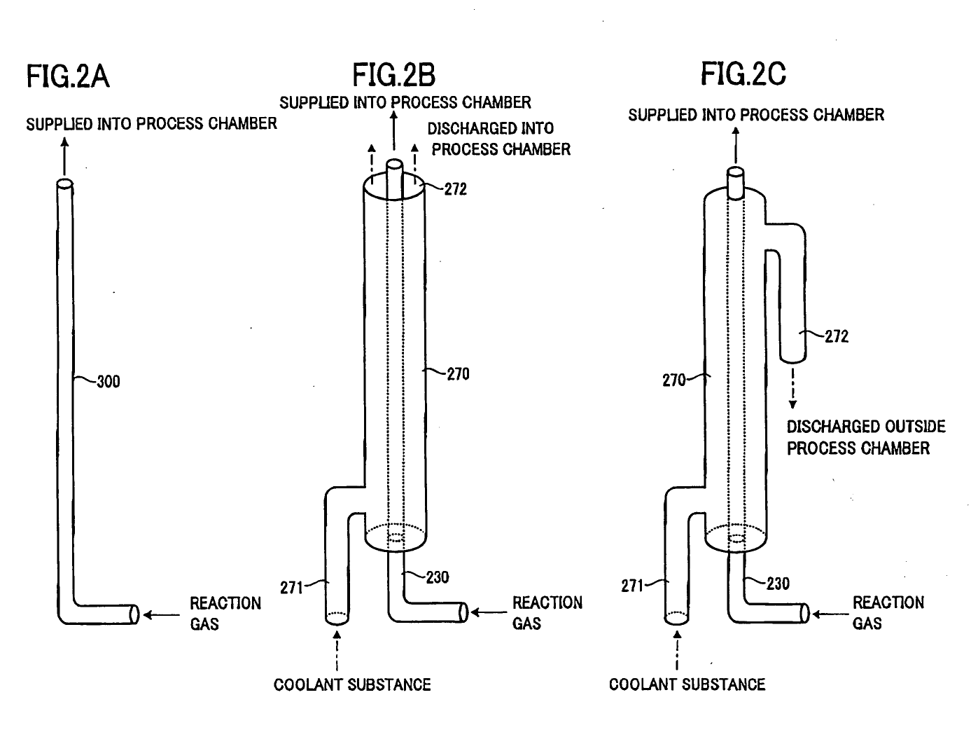

Hereinafter the circulation pipe 270 in the first embodiment will be described based on FIG. 2B.

As shown in FIG. 2B, the circulation pipe 270 in this embodiment is so provided as to cover at least the part of the nozzle 230 opposed to the heater 206 and circulates a substance other than the reaction gas inside thereof. More specifically, the circulation pipe 270 has a cylindrical shape with a closed lower end and an opened upper end, and an introduction part 271 for introducing the substance other than the reaction gas into the inside of the circulation pipe 270 is provided at a side surface near the lower end of the circulation pipe 270. The opened upper end of the circulation pipe 270 serves as a discharge part 272 for discharging the substance other than the reaction gas that have flown through the circulation pipe 270, and the substance other than the reaction gas is discharged to the inside of the process tube 203 after flowing through the circulation pipe 270. Thus, at least the part of the nozzle 230 opposed to the heater 206 has the double structure by the circulation pipe 270.

The substance other than the reaction gas is a coolant substance for cooling the nozzle 230 and is a gas, a liquid, or a solid. Therefore, the circulation pipe 270 lowers the temperature of the reaction gas passing through the nozzle 230 to a temperature lower than the temperature inside the process tube 203 (process chamber 201) by several degrees to several hundreds of degrees by circulating thereinside the coolant substance that is the substance other than the reaction gas. Referring to FIG. 1, the first nozzle 230a is not disposed in the region opposed to the heater 206, and the second nozzle 230b, the third nozzle 230c, and the fourth nozzle 230d are disposed in the region opposed to the heater 206. Therefore, it is preferable to dispose the circulation pipe 270 in such a fashion that at least the parts of the second nozzle 230b, the third nozzle 230c, and the fourth nozzle 230d opposed to the heater 260 are covered with the circulation pipe 270. In this embodiment, since the coolant substance after passing through the circulation pipe 270 is discharged to the process chamber 201, it is preferable to use a gaseous substance as the coolant substance.

Shown in FIG. 2A is a nozzle 300 in Comparative Example.

As shown in FIG. 2A, the nozzle 300 in Comparative Example has a shape similar to that of the nozzle 230 of the first embodiment and a second embodiment described later in this specification and disposed at a position opposed to a heater (not shown). During film formation processing, a reaction gas temperature inside the nozzle 300 is raised to a temperature similar to that inside a process chamber (not shown).

Hereinafter, a circulation pipe 270 in the second embodiment will be described based on FIG. 2C.

As shown in FIG. 2C, the circulation pipe 270 in this embodiment has a cylindrical shape with closed upper and lower ends, and the introduction part 271 for introducing a substance other than a reaction gas into the circulation pipe 270 is provided at a side surface near the lower end of the circulation pipe 270. A discharge part 272 for discharging the substance other than the reaction gas circulated inside the circulation pipe 270 is provided at a side surface near the upper end of the circulation pipe 270, so that the substance other than the reaction gas is discharged to outside of the process tube 203 (process chamber 201), i.e. to a site separated from the process chamber 201. In this embodiment, since the coolant substance after passing through the circulation pipe 270 is discharged outside the process chamber 201, it is possible to use not only a gaseous substance but also a liquid substance such as a cooling water and a solid substance such as a powder as the coolant substance.

In the description of the second embodiment, the components having the identical functions of those of the first embodiment are denoted by the same reference numerals in the drawings, and description of the identical components is omitted.

Hereinafter, Example 1 and Example 2 will be described.

### EXAMPLE 1

With the use of the substrate processing apparatus 100 provided with the circulation pipe 270 in the first embodiment, a Si₃N₄ film formation processing was performed. Processing conditions were as follows: processing temperature was 400° C. to 780° C.; processing pressure was 25 to 270 Pa; reaction gaseous species was a silane-based gas such as SiH₄ and an organic silane-based gas such as BTBAS (SiH₂Cl₂ gas in this example); reaction gas supply flow rate was 0.03 to 0.5 slm; added gas species was NH₃ gas; and added gas supply flow rate was 0.5 to 1 slm or more. The reaction gas and the added gas were separately supplied from the nozzle 230 and an added gas nozzle (not shown in FIG. 1) to the process tube 203, and the substance other than the reaction gas was circulated as a coolant substance inside the circulation pipe 270 to supply the coolant substance to the process tube 203. The type of the coolant substance was a gas such as a NH₃ gas and a diluted NH₃ gas diluted with an inert gas such as N₂, and a supply flow rate of the coolant substance was 0.09 slm or more. A temperature of the reaction gas supplied from the nozzle 230 was higher than a temperature inside the process tube 203 (process chamber 201) by several degrees to several hundreds of degrees. Particularly, when the temperature of the nozzle 230 was lowered to 600° C. or less, deposition of a film inside the nozzle 230 was prevented since SiH₂Cl₂ was not heat-decomposed inside the nozzle 230.

In this example, since the gas that is necessary for film formation but is not capable of film formation by itself, i.e. a gas containing at least one (N) of a plurality of elements (Si, N) forming the film (Si₃N₄) and not capable of depositing a film by itself, such as the NH₃ gas that is identical with the added gas, was used as the coolant substance, it is possible to prevent ratios of the SiH₂Cl₂ gas and the NH₃ gas from changing by controlling the supply flow rate of the NH₃ gas serving as the added gas and the supply flow rate of the NH₃ gas serving as the coolant substance, thereby making it possible to form films having uniformity and homogeneity that are equal to or superior to those achieved by conventional technologies. That is, the flow rate of the coolant substance to be discharged into the process tube 203 from the discharge part 272 after passing through the circulation pipe 270 is actively controlled to be used as a part of the added gas.

### EXAMPLE 2

With the use of the substrate processing apparatus 100 provided with the circulation pipe 270 in the second embodiment, a Si₃N₄ film formation processing was performed. Processing conditions were as follows: processing temperature was 400° C. to 780° C.; processing pressure was 25 to 270 Pa; reaction gaseous species was a silane-based gas such as SiH₄ and an organic silane-based gas such as BTBAS (SiH₂Cl₂ gas in this example); reaction gas supply flow rate was 0.03 to 0.5 slm; added gas species of NH₃ gas; and added gas supply flow rate was 0.5 to 1 slm or more. The reaction gas and the added gas were separately supplied from the nozzle 230 and an added gas nozzle (not shown in FIG. 1) to the process tube 203, and the substance other than the reaction gas was circulated as a coolant substance inside the circulation pipe 270 to be supplied to the process tube 203. The type of the coolant substance was a N₂ gas or a dry air, and a supply flow rate of the coolant substance was 1 to 8 slm or more. A temperature of the reaction gas supplied from the nozzle 230 was higher than a temperature inside the process tube 203 (process chamber 201) by several degrees to several hundreds of degrees.

In this example, since the N₂ gas or the dir air was used as the coolant substance, ratios and concentrations of the SiH₂Cl₂ gas and NH₃ gas can be changed in the case where the coolant substance was discharged into the process tube 203 to influence on a film formation speed. Also, it is considered that a reaction different from the desired reaction can occur to influence on a film quality. Therefore, the coolant substance was discharged outside the process tube 203 from the discharge part 272.

As described above, according to this invention, since it is possible to reduce the temperature of the reaction gas passing through the nozzle 230 to a temperature lower than the temperature inside the process tube 203 (process chamber 201) by circulating the coolant substance in the circulation pipe 270, it is possible to suppress formation of a film inside the nozzle 230. Thus, it is possible to reduce an amount of contaminants generated from the nozzle 230. Also, since it is possible to extend the replacement or maintenance cycle of the nozzle 230, it is possible to realize improvement in operation rate of the apparatus.

Though the apparatus wherein at least the part of the nozzle 230 opposed to the heater 206 has the double structure due to the circulation pipe 270 has been described in the above examples, a structure of providing the circulation pipe 270 in a multiplexed fashion on at least the part of the nozzle 230 opposed to the heater 206 may be employed.

Example 1 will be described in further details.

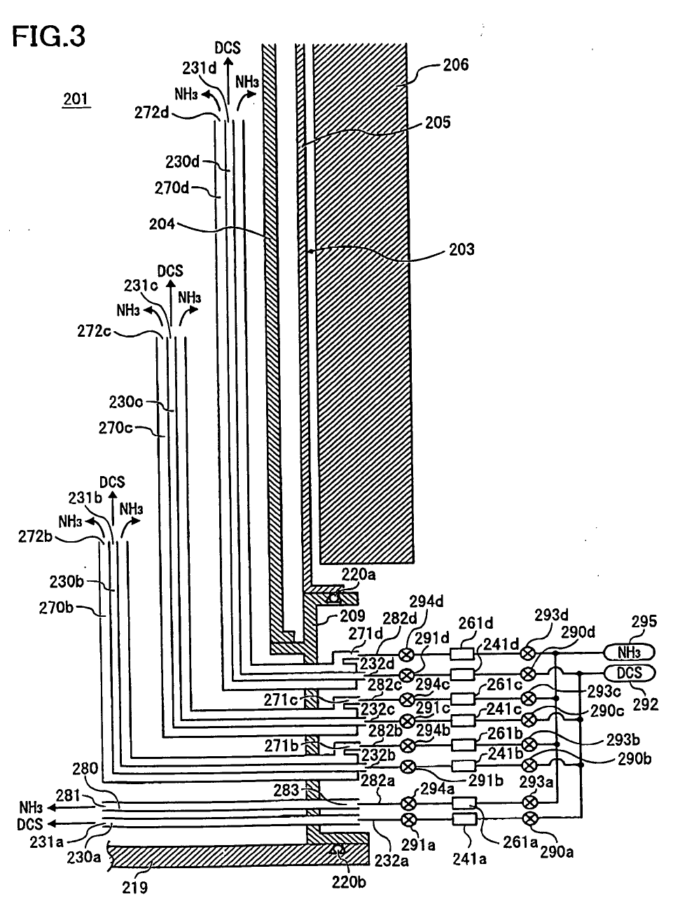

FIG. 3 is a schematic diagram showing a detailed structure of the gas supply system of the substrate processing apparatus 100 used in Example 1. Note that SiH₂Cl₂ (dichlorosilane) is hereinafter abbreviated to DCS.

A NH₃ short nozzle 280 corresponding to the above-described added gas nozzle is formed in the vicinity of the first nozzle 230a serving as the DCS short nozzle and extended in a horizontal direction which is parallel to the first nozzle 230a. A gas injection aperture 281 of the NH₃ short nozzle 280 is opened at a position substantially the same as the gas injection aperture 231a of the first nozzle 230a and in the horizontal direction inside the process tube 203. Therefore, like DCS, NH₃ is supplied from an upstream side of the substrate alignment region, which is further upstream from the heat insulating plate alignment region, to the process tube 203.

A first circulation pipe 270b, a second circulation pipe 270c, and a third circulation pipe 270d are provided in such a fashion as to cover the second nozzle 230b, the third nozzle 230c, and the fourth nozzle 230d, respectively. A discharge part 272b of the first circulation pipe 270b, a discharge part 272c of the second circulation pipe 270c, and a discharge part 272d of the third circulation pipe 270d are opened upward inside the process tube 203 at a position substantially the same as the gas injection aperture 231b of the second nozzle 230b, at a position substantially the same as the gas injection aperture 231c of the third nozzle 230c, and at a position substantially the same as the gas injection aperture 231d of the fourth nozzle 230d, respectively. That is, the discharge parts 272b, 272c, and 272d serving as NH₃ gas injection apertures are disposed at different positions along the vertical direction like the DCS gas injection apertures 231b, 231c, and 231d in the substrate alignment region. Therefore, it is possible to supply NH₃ at the intermediate points that are the same as those for supplying DCS, thereby making it possible to replenish NH₃ consumed as flowing from the upstream to the downstream from the intermediate points in the substrate alignment region. Also, since the discharge parts 272b, 272c, and 272d are opened inside the process chamber 201 at the positions that do not overlap with one another in the vertical direction, it is possible to supply NH₃ uniformly inside the process chamber 201.

As described above, the first gas supply pipe 232a, the second gas supply pipe 232b, the third gas supply pipe 232c, and the fourth gas supply pipe 232d are connected to the first nozzle 230a, the second nozzle 230b, the third nozzle 230c, and the fourth nozzle 230d, respectively, and the first gas supply pipe 232a, the second gas supply pipe 232b, the third gas supply pipe 232c, and the fourth gas supply pipe 232d are provided with the first MFC 241a, the second MFC 241b, the third MFC 241c, and the fourth MFC 241d, respectively. Also, opening/closing valves 290a, 290b, 290c, and 290d are provided at an upstream side of the MFCs 241a, 241b, 241c, and 241d of the first gas supply pipe 232a, the second gas supply pipe 232b, the third gas supply pipe 232c, and the fourth gas supply pipe 232d, respectively, and opening/closing valves 291a, 291b, 291c, and 291d are provided at a downstream side. Also, a DCS supply source 292 is connected to the first gas supply pipe 232a, the second gas supply pipe 232b, the third gas supply pipe 232c, and the fourth gas supply pipe 232d.

A first NH₃ supply pipe 282a is connected to an introduction part 283 of the NH₃ short nozzle 280. Also, a second NH₃ supply pipe 282b, a third NH₃ supply pipe 282c, and a fourth NH₃ supply pipe 282d are connected to an introduction part 271b of the first circulation pipe 270b, an introduction part 271c of the second circulation pipe 270c, and an introduction part 271d of the third circulation pipe 270d, respectively. A first NH₃ MFC 261a, a second NH₃ MFC 261b, a third NH₃ MFC 261c, and a fourth NH₃ MFC 261d are connected to the first NH₃ supply pipe 282a, the second NH₃ supply pipe 282b, the third NH₃ supply pipe 282c, and the fourth NH₃ supply pipe 282d, respectively. Also, opening/closing valves 293a, 293b, 293c, and 293d are provided at an upstream side of the NH₃ MFCs 261a, 261b, 261c, and 261d of the first NH₃ supply pipe 282a, the second NH₃ supply pipe 282b, the third NH₃ supply pipe 282c, and the fourth NH₃ supply pipe 282d, respectively, and opening/closing valves 294a, 294b, 294c, and 294d are provided at a downstream side. Also, a NH₃ supply source 295 is connected to the first NH₃ supply pipe 282a, the second NH₃ supply pipe 282b, the third NH₃ supply pipe 282c, and the fourth NH₃ supply pipe 282d.

Since the NH₃ MFCs 261a, 261b, 261c, and 261d are provided for the NH₃ supply pipes 282a, 282b, 282c, and 282d, respectively, it is possible to actively control a supply flow rate of NH₃ at the above-described positions inside the process chamber 201, and it is possible to carefully control the NH₃ flow rate as required by fine-adjustment or the like of the NH₃ flow rate at the above-described positions inside the process chamber 201. Particularly, in the NH₃ supply pipes 282b, 282c, and 282d connected to the first circulation pipe 270b, the second circulation pipe 270c, and the third circulation pipe 270d, respectively, it is possible to adjust a NH₃ concentration at each of the above-described points in the substrate alignment region inside the process chamber 201 while cooling the nozzles 230b, 230c, and 230d by controlling the NH₃ flow rates respectively by the 3 MFCs 261b, 261c, and 261d.

Since the added gas (NH₃) is used as the cooling gas in Example 1, it is unnecessary to separately provide a gas line for the nozzle cooling gas that performs nozzle cooling only. Also, since the circulation pipes 270b, 270c, and 270d for supplying NH₃ are provided at the positions same as those of the nozzles 230b, 230c, and 230d in such a fashion as to cover the nozzles 230b, 230c, and 230d, it is possible to reduce the number of nozzle provision points as compared to the case of separately providing NH₃ long nozzles in the same manner as providing the DCS long nozzles 230b, 230c, and 230d.

In FIG. 3, the components that are substantially identical to those described by using FIGS. 1 and 2 are denoted by the same reference numerals, and description of the identical components is omitted.

Hereinafter, modification examples will be described.

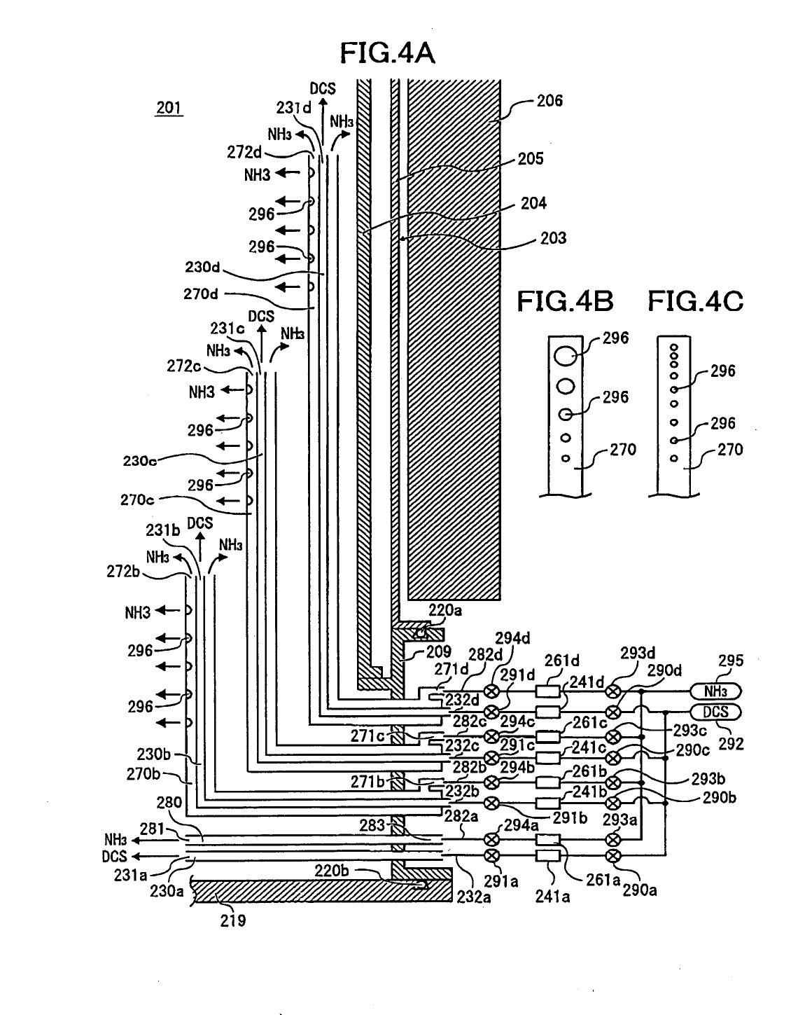

FIG. 4A is a schematic diagram showing a detailed structure of a gas supply system of a substrate processing apparatus 100 used in a first modification example. Modification Example 1 is different from Example 1 in that a NH₃ injection aperture 296 is provided on a side wall of the circulation pipes 270b, 270c, and 270d. The number of the NH₃ injection aperture 296 may be one in each of the circulation pipes 270b, 270c, and 270d, and it is preferable to provide a plurality of the NH₃ injection apertures 296 at positions that does not overlap with one another in the vertical direction in each of the circulation pipes 270b, 270c, and 270d. Also, it is preferable that the NH₃ injection apertures 296 of the circulation pipes 270b, 270c, and 270d do not overlap with one another in the vertical direction. By providing the NH₃ injection apertures 296 at positions that do not overlap with one another in the vertical direction, it is possible to supply NH₃ more uniformly to the whole process chamber 201.

Each of the size (aperture area, diameter), the number of apertures, an alignment pitch, and the like of the NH₃ injection apertures 296 may be the same or different. For example, the NH₃ injection apertures 296 may be increased in size as the position of the NH₃ injection aperture 296 approaches to an upper end of the circulation pipe 270 that is placed downstream in the NH₃ supply as shown in FIG. 4B or may be decreased in pitch (increased in number of apertures) as the position of the NH₃ injection aperture 296 approaches to the upper end of the circulation pipe 270 as shown in FIG. 4C, thereby making it possible to supply NH₃ much more uniformly to the process chamber 201.

In FIG. 4A, the components that are substantially identical to those described in Example 1 are denoted by the same reference numerals, and description of the identical components is omitted.

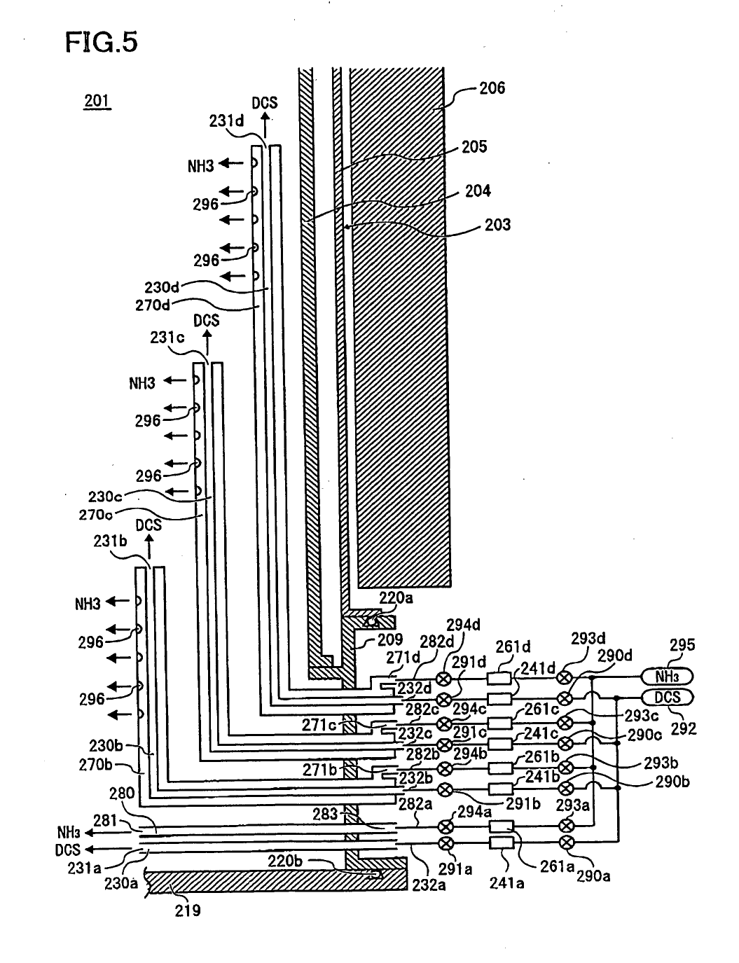

FIG. 5 is a schematic diagram showing a detailed structure of a gas supply system of a substrate processing apparatus 100 used in a second modification example. Modification Example 2 is different from Modification Example 1 in that the upper ends of the circulation pipes 270b, 270c, and 270d, i.e. the discharge parts 272b, 272c, and 272d, are closed, and that NH₃ flowing through the circulation pipes 270b, 207c, and 270d is supplied to the process chamber 201 only from the NH₃ injection apertures 296 provided on the side walls of the circulation pipes 270b, 207c, and 270d. In Modification Example 1, since an amount of NH₃ flowing through the circulation pipes 270b, 207c, and 270d and injected from the discharge parts 272b, 272c, and 272d opened at the upper ends of the circulation pipes 270b, 270c, and 270d is large, an amount of NH₃ injected from the NH₃ injection apertures 296 is small. In contrast, since the upper ends of the circulation pipes 270b, 270c, and 270d are closed in Modification Example 2, NH₃ flowing through the circulation pipes 270b, 207c, and 270d is injected only from the NH₃ injection apertures 296 provided on the side walls of the circulation pipes 270b, 207c, and 270d, thereby making it possible to more uniformly supply NH₃ to the whole process chamber 201.

In FIG. 5, the components that are substantially identical to those described in Modification Example 1 are denoted by the same reference numerals, and description of the identical components is omitted.

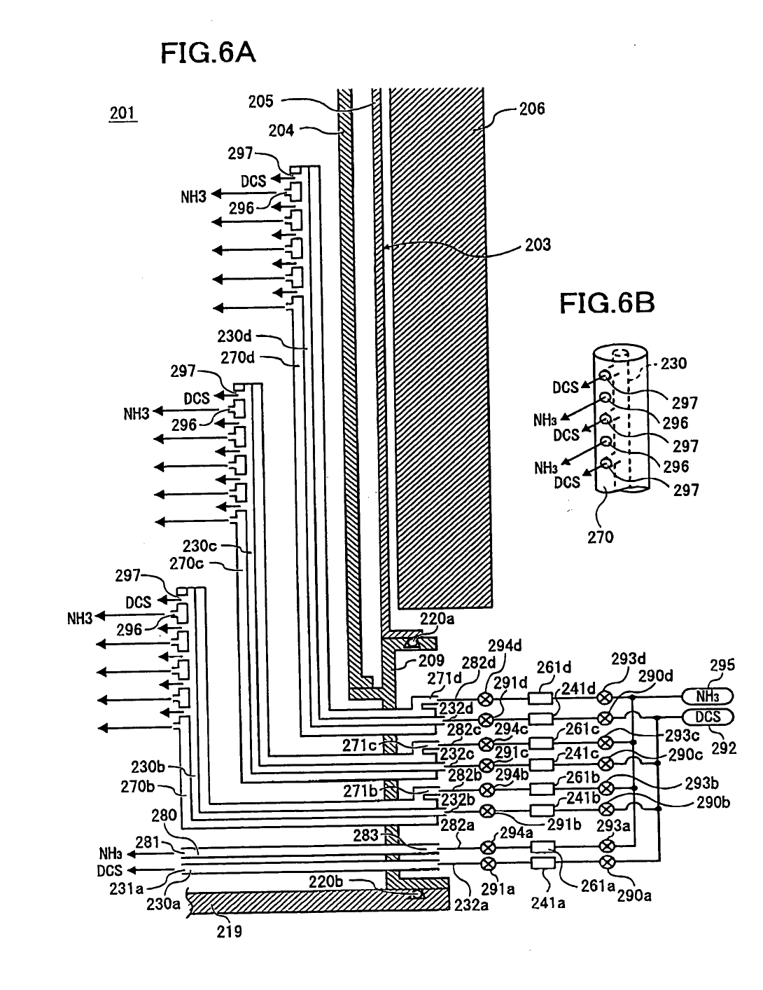

FIG. 6A is a schematic diagram showing a detailed structure of a gas supply system of a substrate processing apparatus 100 used in a third modification example. Modification Example 3 is different from Modification Example 2 in that not only the upper ends of the circulation pipes 270b, 270c, and 270d but also the upper ends of the nozzles 230b, 230c, and 230d, i.e. the gas injection apertures 231b, 231c, and 231d, are closed, and DCS injection apertures 297 communicated with the process chamber 201 are provided on the side walls of the nozzles 230b, 230c, and 230d for supplying DCS so that DCS is injected in the horizontal direction from the side walls of the nozzle 230b, 230c, and 230d. The DCS injection aperture 297 is opened on each of the side walls of the circulation pipes 270b, 270c, and 270d and so formed as to provide communication between the nozzles 230b, 230c, and 230d and the process chamber 201, thereby connecting the side walls of the nozzles 230b, 230c, and 230d to the side walls of the circulation pipes 270b, 270c, and 270d. That is, the DCS injection apertures 297 are connected to the nozzle 230b, 230c, and 230d as crossing over the circulation pipes 270b, 270c, and 270d in the horizontal direction, and DCS and NH₃ are not mixed inside the nozzles 230b, 230c, and 230d as well as inside the circulation pipes 270b, 270c, and 270d. As shown in FIG. 6B, the NH₃ injection aperture 296 and the DCS injection aperture 297 are alternated in the vertical direction so that it is possible to more uniformly supply both of DCS and NH₃ to the whole process chamber 201.

Each of the size (aperture area, diameter), the number of apertures, an alignment pitch, and the like of the DCS injection apertures 297 may be varied as in the NH₃ injection apertures 296.

In FIG. 6, the components that are substantially identical to those described in Modification Example 2 are denoted by the same reference numerals, and description of the identical components is omitted.

This invention encompasses the following embodiments.

(1) A substrate processing apparatus comprising:

a reaction container for performing a processing for generating a film containing a plurality of elements on a substrate;

a heater for heating an inside of the reaction container;

at least one nozzle that is provided inside the reaction container in such a fashion that at least a part thereof is opposed to the heater for supplying a first gas containing at least one of the plurality of elements forming the film and capable of depositing a film by itself into the reaction container; and

a circulation pipe that is provided in such a fashion as to cover at least the part of the nozzle opposed to the heater for supplying a second gas containing at least one of the plurality of elements forming the film and not capable of depositing a film by itself into the reaction container after circulating the second gas thereinside.

(2) The substrate processing apparatus according to (1), wherein the number of the nozzle is two or more, and the number of the circulation pipe is the same as the number of the nozzle and each of the circulation pipes corresponds to each of the nozzles.

(3) The substrate processing apparatus according to (2), further comprising:

a first flow rate controller for controlling a supply flow rate of the first gas for each of the nozzles independently, the first gas being supplied from the nozzles into the reaction container; and

a second flow rate controller for controlling a supply flow rate of the second gas for each of the circulation pipes independently, the second gas being supplied from the circulation pipes into the reaction container.

(4) A substrate processing apparatus comprising:

a reaction container for performing a processing for generating a silicon nitride film on a substrate;

a heater for heating an inside of the reaction container;

a plurality of nozzles that are provided inside the reaction container in such a fashion that at least a part of each of the nozzles is opposed to the heater, the nozzles being different in length one another and supplying a silane-based gas into the reaction container; and

a plurality of circulation pipes that are provided in such a fashion as to cover at least the parts of the nozzles opposed to the heater respectively for supplying an ammonium gas into the reaction container after circulating the ammonium gas thereinside.

(5) The substrate processing apparatus according to (1), wherein the circulation pipe is provided with a plurality of gas injection apertures.

(6) The substrate processing apparatus according to (1) wherein each of the nozzle and the circulation pipe is provided with a plurality of gas injection apertures.

(7) The substrate processing apparatus according to (2), wherein each of the circulation pipes is provided with a plurality of gas injection apertures.

(8) The substrate processing apparatus according to (2), wherein each of the nozzles and each of the circulation pipes is provided with a plurality of gas injection apertures.

(9) The substrate processing apparatus according to (2), wherein each of the circulation pipes is provided with a plurality of gas injection apertures, and the gas injection apertures provided on the circulation pipes are disposed at positions that do not overlap with one another in a vertical direction.

(10) The substrate processing apparatus according to (2), wherein each of the nozzles and each of the circulation pipes is provided with a plurality of gas injection apertures; the gas injection apertures provided on the nozzles are disposed at positions that do not overlap with one another in a vertical direction, and the gas injection apertures provided on the circulation pipes are disposed at positions that do not overlap with one another in the vertical direction.

(11) The substrate processing apparatus according to (4), wherein the silane-based gas is dichlorosilane, and the circulation pipes are composed to maintain a temperature of the nozzles to 600° C. or less by circulating an ammonium gas thereinside.

(12) A method for manufacturing a semiconductor device, comprising the steps of:

transferring a substrate into a reaction container;

performing, in a state where an inside of the reaction container is heated by a heater, a processing for generating a film containing a plurality of elements on the substrate by supplying a first gas containing at least one of the plurality of elements forming the film and capable of depositing a film by itself from at least one nozzle provided inside the reaction container in such a fashion that at least a part thereof is opposed to the heater into the reaction container and supplying a second gas containing at least one of the plurality of elements forming the film and not capable of depositing a film by itself from a circulation pipe provided in such a fashion as to cover at least the part of the nozzle opposed to the heater into the reaction container after circulating the second gas thereinside; and

transferring the processed substrate from the reaction container.

(13) A substrate processing apparatus comprising:

a reaction container for processing a substrate;

a heater for heating an inside of the reaction container;

at least one nozzle that is provided inside the reaction container in such a fashion that at least a part thereof is opposed to the heater for supplying a reaction gas into the reaction container; and

a circulation pipe that is provided in such a fashion as to cover at least the part of the nozzle opposed to the heater for circulating a substance other than the reaction gas thereinside.

(14) A method for manufacturing a semiconductor device, comprising the steps of:

transferring a substrate into a reaction container;

processing, during heating an inside of the reaction container by a heater, the substrate by supplying a reaction gas into the reaction container by at least one nozzle provided inside the reaction container in such a fashion that at least a part thereof is opposed to the heater; and

transferring the processed substrate from the reaction container, wherein

a substance other than the reaction gas is circulated inside the circulation pipe so provided as to cover the part of the nozzle opposed to the heater in the step of processing the substrate.

(15) The substrate processing apparatus according to (13), wherein the circulation pipe is provided with an introduction part for introducing the substance other than the reaction gas into the circulation pipe and a discharge part for discharging the substance other than the reaction gas after being circulated inside the circulation pipe; and the discharge part is communicated with the reaction container so that the substance other than the reaction gas is discharged to the reaction container.

(16) The substrate processing apparatus according to (13) wherein the circulation pipe is provided with an introduction part for introducing the substance other than the reaction gas into the circulation pipe and a discharge part for discharging the substance other than the reaction gas after being circulated inside the circulation pipe; and the discharge part is communicated with an outside of the reaction container so that the substance other than the reaction gas is discharged outside the reaction container.

(17) The substrate processing apparatus according to (13), wherein the substance other than the reaction gas is a gas, a liquid, or a solid.

(18) The substrate processing apparatus according to (13) wherein the substance other than the reaction gas is a coolant substance for cooling the nozzle.

(19) The substrate processing apparatus according to (13), wherein the circulation pipe is composed to reduce a temperature of the reaction gas passing through the nozzle to a temperature lower than a temperature inside the reaction container by several degrees to several hundreds of degrees by circulating the substance other than the reaction gas thereinside.

This invention is useful for substrate processing apparatuses for processing substrates such as semiconductor wafers and glass substrates and semiconductor device manufacturing methods requiring realization of improvement in operation rate.

What is claimed is:

1. A substrate processing apparatus comprising:
a reaction container for performing a processing for generating a film containing a plurality of elements on a substrate;
a heater for heating an inside of the reaction container;
at least one nozzle that is provided inside the reaction container in such a fashion that at least a part thereof is opposed to the heater for supplying a first gas containing at least one of the plurality of elements forming the film and capable of depositing a film by itself into the reaction containers and
a circulation pipe that is provided in such a fashion as to cover at least the part of the nozzle opposed to the heater for supplying a second gas containing at least one of the plurality of elements forming the film and not capable of depositing a film by itself into the reaction container after circulating the second gas thereinside.

2. The substrate processing apparatus according to claim 1, wherein the number of the nozzle is two or more, and the number of the circulation pipe is the same as the number of the nozzle and each of the circulation pipes corresponds to each of the nozzles.

3. The substrate processing apparatus according to claim 2, further comprising:
a first flow rate controller for controlling a supply flow rate of the first gas for each of the nozzles independently, the first gas being supplied from the nozzles into the reaction container; and
a second flow rate controller for controlling a supply flow rate of the second gas for each of the circulation pipes independently, the second gas being supplied from the circulation pipes into the reaction container.

4. A substrate processing apparatus comprising:
a reaction container for performing a processing for generating a silicon nitride film on a substrate;
a heater for heating an inside of the reaction container;
a plurality of nozzles that are provided inside the reaction container in such a fashion that at least a part of each of the nozzles is opposed to the heater, the nozzles being different in length one another and supplying a silane-based gas into the reaction container; and
a plurality of circulation pipes that are provided in such a fashion as to cover at least the parts of the nozzles opposed to the heater respectively for supplying an ammonium gas into the reaction container after circulating the ammonium gas thereinside.

5. The substrate processing apparatus according to claim 1, wherein the circulation pipe is provided with a plurality of gas injection apertures.

6. The substrate processing apparatus according to claim 1, wherein each of the nozzle and the circulation pipe is provided with a plurality of gas injection apertures.

7. The substrate processing apparatus according to claim 2, wherein each of the circulation pipes is provided with a plurality of gas injection apertures.

8. The substrate processing apparatus according to claim 2, wherein each of the nozzles and each of the circulation pipes is provided with a plurality of gas injection apertures.

9. The substrate processing apparatus according to claim 2, wherein each of the circulation pipes is provided with a plurality of gas injection apertures, and the gas injection apertures provided on the circulation pipes are disposed at positions that do not overlap with one another in a vertical direction.

10. The substrate processing apparatus according to claim 2, wherein each of the nozzles and each of the circulation pipes is provided with a plurality of gas injection apertures; the gas injection apertures provided on the nozzles are disposed at positions that do not overlap with one another in a vertical direction, and the gas injection apertures provided on the circulation pipes are disposed at positions that do not overlap with one another in the vertical direction.

11. The substrate processing apparatus according to claim 4, wherein the silane-based gas is dichlorosilane, and the circulation pipes are composed to maintain a temperature of the nozzles to 600° C. or less by circulating an ammonium gas thereinside.

12. A method for manufacturing a semiconductor device, comprising the steps of:
transferring a substrate into a reaction container;
performing, in a state where an inside of the reaction container is heated by a heater, a processing for generating a film containing a plurality of elements on the substrate by supplying a first gas containing at least one of the plurality of elements forming the film and capable of depositing a film by itself from at least one nozzle provided inside the reaction container in such a fashion that at least a part thereof is opposed to the heater into the reaction container and supplying a second gas containing at least one of the plurality of elements forming the film and not capable of depositing a film by itself from a circulation pipe provided in such a fashion as to cover at least the part of the nozzle opposed to the heater into the reaction container after circulating the second gas thereinside; and
transferring the processed substrate from the reaction container.
